(19) United States
(12) Patent Application Publication
(10) Pub. No.: US 2018/0283955 A1
(43) Pub. Date: Oct. 4, 2018

(54) METHOD OF ASSESSING MULTIPLE DISTRIBUTION TRANSFORMER LOADING CONDITIONS IN ONE AREA USING AN AUTONOMOUS DRONE

(71) Applicant: MING DONG, CALGARY (CA)

(72) Inventor: MING DONG, CALGARY (CA)

(73) Assignee: MING DONG, CALGARY (CA)

(21) Appl. No.: 15/974,079

(22) Filed: May 8, 2018

(51) Int. Cl. G01J 5/00; G05D 1/00; G05D 1/10; G01R 31/02

(52) U.S. Cl. CPC G01J 5/0096; G05D 1/0011; B64C 39/024; G01J 5/00; G01R 31/027; G05D 1/101

(57) ABSTRACT

What are disclosed here are a method and its embodiments to assess the loading of distribution transformers in one area using autonomous drones that can be automatically piloted according to GPS coordinates to measure every target transformer's temperature data or thermal images in one area. The drone has a GPS system and can send its GPS coordinates wirelessly to ground crews' computing device. The computing device compares the drone's current GPS coordinates with the GPS coordinates of target transformers and guide the drone to fly to each target transformer location. The drone stops above each target transformer and use its thermography camera to measure the transformer's temperature data or thermal images. The temperature data or thermal images can be processed to identify overloaded transformers, transformers with outages and transformers with loading deviations that can be considered for load balance.

### FIELD OF THE INVENTION

This disclosure relates to a method of assessing the loading conditions of multiple distribution transformers in one area using an autonomous drone system that can be automatically piloted with respect to the target transformers' GPS coordinates.

### BACKGROUND OF THE INVENTION

In high-density areas such as certain urban residential communities, assessing a large amount of transformers' loading conditions is an important task due to the following reasons:

1. Assessing area transformer loading conditions can help electric utility companies identify overloaded transformers. According to the assessment results, utility companies can upgrade transformer sizes and this can help prevent transformer outages caused by overloading. Unexpected outages of these transformers could affect customer satisfaction and lead to economic loss. Residential transformers are normally not designed for higher reliability criterion which upper stream of distribution systems such as substation transformers and feeders are required to follow. This means the outage of a residential transformer often results in hours of effort for the replacement of the failed transformer in order to restore power supply. During this period of time, connected residential customers would suffer from the power outage with no other means of fast alleviation except employing backup generators. This consequence could become quite severe to residential customers in extreme weathers, whether it is hot or cold.

2. Assessing area transformer loading conditions can help utility companies balance the loadings between adjacent transformers. This can help increase the power supply efficiency, reduce transformer loss and extend the service life of transformers.

3. During an outage event in a community, utility emergency crews are called to the community. Quick assessment of transformer loading can help emergency crews locate the fault. The transformer with minimum loading is the problematic transformer and should be replaced.

To respond to the above needs, this disclosure presents a novel drone based method to quickly assess the loading conditions of multiple service transformers in one area aerially. Instead of directly measuring the loading, the drone flies to target transformers to and stop over the target transformers to measure the temperatures or thermal images of transformers using thermography cameras. In addition, the drone can be wirelessly piloted with respect to the target transformers' GPS coordinates and automatically arrive at each target transformer for temperature measurement. The measured temperature data or thermal images can be saved locally with the drone system. Then the captured temperature data or thermal images can be retrieved and processed manually or by computer to identify the overloaded transformers, transformers having outages or transformers with loading deviation to be considered for transformer loading balance.

Previously, patents U.S. Pat. No. 4,818,990A and US20120250010A1 use drones to inspect power lines; US20170097435A1 uses autonomous aerial crafts to detect power lines based on magnetic fields; US20170285092A1 uses drones to detect and locate power line corona discharges and electrical arcs. None of those above aims the assessment of multiple transformers' loading conditions in one area in an autonomous way.

### SUMMARY OF THE INVENTION

What are disclosed here are a method and its embodiments to assess the loading of distribution transformers in one area using autonomous drones that can be automatically piloted according to GPS coordinates to measure every target transformer's temperature data or thermal images in one area. This disclosure works as follows: crews go to the area of interest and select the transformers to be assessed on their computing device such as computers or tablets. Then the drone is launched into the air. The drone has a GPS system and can continuously send its GPS coordinates wirelessly to ground crews' computing device. The computing device compares the drone's current GPS coordinates with the GPS coordinates of target transformers. Movement commands are generated based on GPS coordinate comparison to guide the drone to fly to each target transformer location. After the drone arrives, it stops above the transformer and use its thermography camera to measure the transformer's temperature data or thermal images. The transformer's temperature data or thermal images are saved locally with the drone system and can be retrieved and processed later. The temperature data or thermal images can be processed to identify overloaded transformers, transformers with outages and transformers with loading deviations that can be considered for load balance.

### BRIEF DESCRIPTION OF THE DRAWINGS

A clear understanding of the key features of the invention summarized above may be had by reference to the appended drawings, which illustrate the method and system of the invention, although it will be understood that such drawings depict exemplary embodiments of the invention and, therefore, are not to be considered as limiting its scope with regard to other embodiments which the invention is capable of contemplating. Accordingly:

FIG. 1 is an illustration of the overall method for assessing multiple distribution transformer loading conditions using an autonomous drone according to an exemplary embodiment of the present disclosure.

FIG. 2 is an illustration of the system using the said method according to an exemplary embodiment of the present disclosure.

FIG. 3 is a flowchart illustrating a process of controlling the drone's movement remotely by comparing GPS coordinates according to an exemplary embodiment of the present disclosure.

FIG. 4 is a flowchart illustrating a process of identifying overloaded transformers, transformers having outages and transformers with loading deviation according to a first exemplary embodiment.

FIG. 5 is a flowchart illustrating a process of identifying overloaded transformers, transformer having outages and transformers.

### DETAILED DESCRIPTION OF THE INVENTION

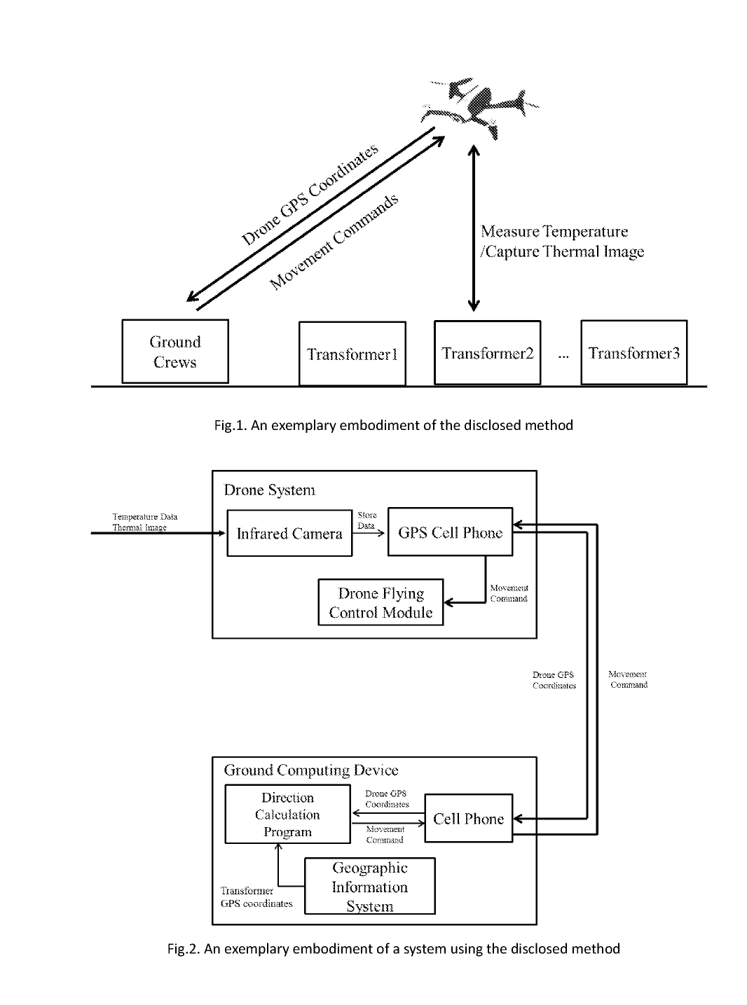

An exemplary embodiment of the overall method of the disclosed is shown in FIG. 1.

It comprises a few steps:

1. Utility crews go to an area and select the target transformers using utility geographic information system or electronic map system installed on their computing device. These systems will be able to provide the GPS coordinates of the selected target transformers.

2. Then the crews launch the drone to the air.

3. The drone reports its GPS coordinates to the ground computing device. The ground computing device compares the drone's GPS coordinates with the GPS coordinates of the selected transformers. Based on the differences of GPS coordinates between the drone and the transformers, movement commands will be generated and sent to the drone. The drone will then fly towards that transformer at a pre-set height. This same method is repeated to guide the drone to visit all selected transformers.

4. Once the drone arrives at a target transformer, it stops above it. The thermography camera the drone carries will be switched on to measure the temperature below it or take thermal images. This same method is repeated to measure the temperatures or thermal images of all target transformers. The measurement data can be stored to a data storage module the drone carries.

5. After all data is collected, the drone flies back to its original GPS coordinates (where the crews are) and lands. The data is then retrieved from the drone's data storage module and processed either manually or by computer to identify overloaded transformers, transformers having outages and transformers with loading deviations that can be considered for load balance.

An exemplary embodiment of a system using the said method is shown in FIG. 2. In this embodiment, the drone system comprises a cell phone that can use GPS to locate its current coordinates, can store the measurement data and can use a cell phone app to send the drone's GPS coordinates and receive the movement commands from the ground computing device. The drone carries an infrared camera to measure transformer temperatures and take thermal images. The ground computing device comprises a cell phone and a utility geographic information system and a direction calculation program installed on a computer. The direction calculation program compares the transformer GPS coordinates with the drone's GPS coordinates. Based on the differences, direction vectors are calculated and movement commands are produced and sent through a cell phone app in the ground cell phone to the drone cell phone. The drone cell phone then transfers the movement command to the drone flying control module to operate the drone's movement accordingly. It should be noted in this embodiment two cell phones are used as a GPS locating device and wireless communication devices between the drone and the ground computer. In other embodiments of the said method and system, a cell phone may integrate the wireless communication app, the geographic information system and the direction calculation program all in one piece; in other embodiments of the said method and system, specialized GPS, data storage and communication hardware may be used instead of cell phones.

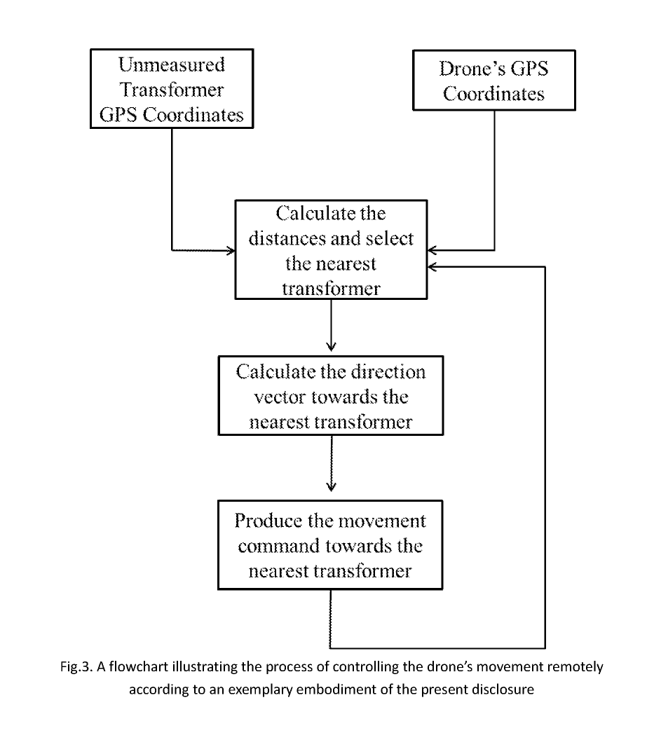

FIG. 3 shows an exemplary embodiment of a flowchart of the said method to control the drone's movement autonomously. The end goal of this control process is to pilot the drone to arrive at each one of the selected target transformers. In the beginning, the distances between the current drone's GPS coordinates and the GPS coordinates of all remaining unmeasured target transforms are calculated. The transformer with minimum distance is selected as the next stop. Then direction vector is calculated as the difference between the GPS coordinates of the drone and GPS coordinates of the transformer. The command including the above direction signal is sent to the drone to move it towards the target transformer. When the direction vector becomes close to zero, it means the drone has arrived at one transformer. It will stop for the infrared camera to take measurements and then move to the next transformer. This process repeats itself until no unmeasured transformer remains.

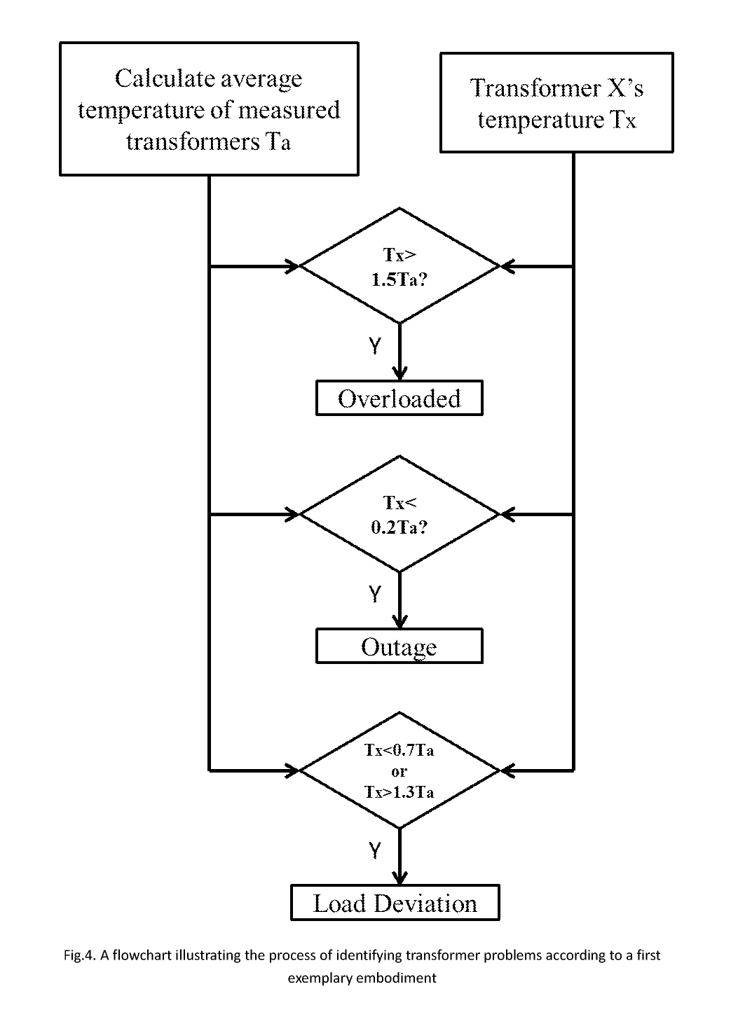

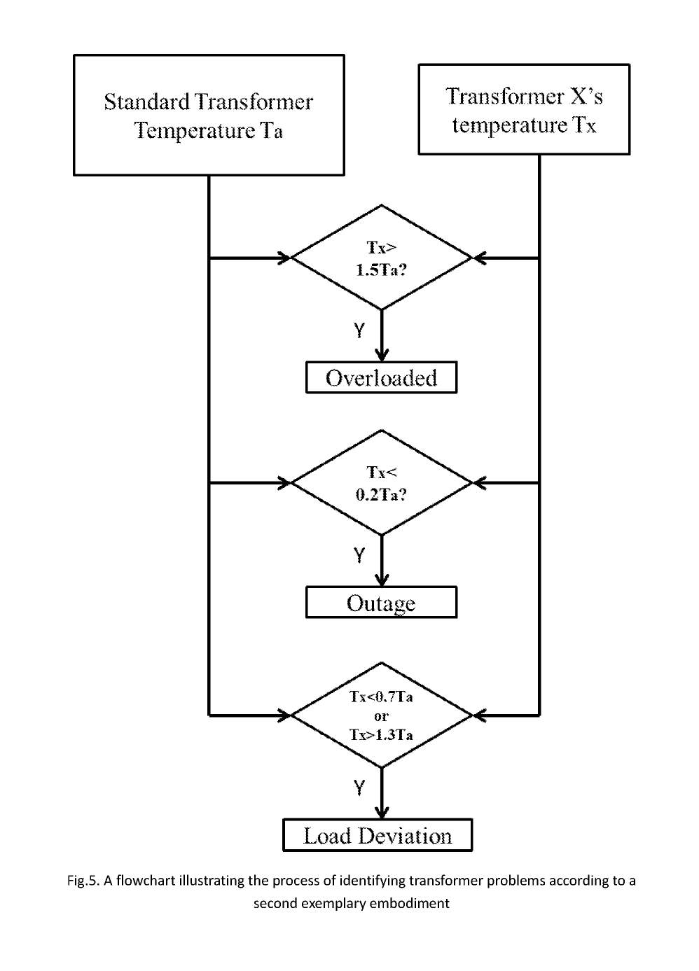

FIG. 4 shows a flowchart of a first exemplary embodiment of the said method to identify overloaded transformers, transformers having outages and transformers with loading deviation. The average temperature of the target transformers in the area is calculated first. A percentage number as the overloading threshold is defined, in this example, 150%. The average temperature multiplied by this percentage number determines the overloading temperature threshold. Transformers with temperatures above this temperature threshold are deemed as overloaded transformers; a percentage number as the outage threshold is defined, in this example, 20%. The average temperature multiplied by this percentage number determines the outage temperature threshold. Transformers with temperatures below this temperature threshold are deemed as transformers having outages; a percentage number as the deviation threshold is defined, in this example, ±30%.

The average temperature multiplied by one plus this percentage number determines the temperature deviation thresholds. Transformers with temperatures above or below the temperature thresholds are deemed as transformers with loading deviation that can be considered for load balance.

FIG. 5 shows a flowchart of a second exemplary embodiment of the said method to identify overloaded transformers, transformers having outages and transformers with loading deviation. A standard transformer temperature is pre-defined based on historical assessment first. A percentage number as the overloading threshold is defined, in this example, 150%. The standard temperature multiplied by this percentage number determines the overloading temperature threshold.

Transformers with temperatures above this temperature threshold are deemed as overloaded transformers; a percentage number as the outage threshold is defined, in this example, 30%. The standard temperature multiplied by this percentage number determines the outage temperature threshold. Transformers with temperatures below this temperature threshold are deemed as transformers having outages; a percentage number as the deviation threshold is defined, for example, ±30%. The standard temperature multiplied by one plus this percentage number determines the temperature deviation threshold. Transformers with temperatures above or below the temperature thresholds are deemed as transformers with loading deviation that can be considered for load balance.

I claim:

1. A method for assessing the loading of multiple transformers in one area, comprising the steps of:
selecting target transformers in one area in GIS system;
launching the drone into the air;
letting the drone fly to each target transformer automatically to measure the transformer's temperature data and thermal images;
processing the measured temperature data and thermal images to complete assessing the loading conditions of multiple transformers in one area.

2. The method of claim 1 further comprising the steps of:
receiving the drone's GPS coordinates;
comparing the drone's GPS coordinates with target transformers' GPS coordinates;
sending commands to drones to fly to target transformers based on the comparison.

3. The method of claim 1 wherein the step of assessing the loading conditions of multiple transformers in one area include some or all of the following objectives:
identifying overloaded transformers;
identifying transformers having outages;
identifying transformers with loading deviation.
